(19) United States
(12) Patent Application Publication
(10) Pub. No.: US 2006/0006761 A1
(43) Pub. Date: Jan. 12, 2006

(54) Ultrasonic process and apparatus with programmable sweep frequency

(76) Inventor: J. Michael Goodson, Skillman, NJ (US)

Correspondence Address: STALLMAN & POLLOCK LLP, SUITE 2200, 353 SACRAMENTO STREET, SAN FRANCISCO, CA, 94111, US

(21) Appl. No.: 11/149,109

(22) Filed: Jun. 9, 2005

Related U.S. Application Data
(60) Provisional application No. 60/578,451, filed on Jun. 9, 2004.

(51) Int. Cl. H01L 41/04

(52) U.S. Cl. 310/317

(57) ABSTRACT

An ultrasonic generator includes a user interface adapted for a user to specify parameters that define a frequency range and a sweep rate for the driving signal, a programmable memory coupled to the user interface for storing the frequency range and sweep rate parameters, and an output circuit responsive to the frequency range and sweep rate parameters for generating the driving signal in the frequency range and at the sweep rate specified by the user. An ultrasonic process includes the steps of programming an ultrasonic generator with parameters specifying a frequency range and a sweep rate of a driving signal output by the generator to one or more ultrasonic transducers used in the ultrasonic process, storing the frequency range and sweep rate parameters in a memory or storage device, and generating a driving signal having a frequency within the specified frequency range and varying at the specified sweep rate.

### RELATED APPLICATION

This application claims priority from U.S. Provisional Application No. 60/578,451, filed Jun. 9, 2004, entitled ULTRASONIC PROCESS AND APPARATUS WITH PROGRAMMABLE SWEEP FREQUENCY, invented by J. Michael Goodson. This provisional application is expressly incorporated herein by reference.

### BACKGROUND OF THE INVENTION

1. Field of the Invention

This invention relates generally to ultrasonic processing methods and apparatus involving one or more ultrasonic transducers energized by an ultrasonic driving signal, and relates more particularly to improving performance by sweeping the driving signal through one or more user-programmable frequency ranges or bandwidths at one or more user-programmable sweep rates.

2. Description of the Relevant Art

An ultrasonic generator supplies an ultrasonic frequency driving signal to drive one or more ultrasonic transducers, which vibrate to supply ultrasonic energy to a cleaning fluid in a tank or to a wire bonding or welding tool, depending on the application. It is known that ultrasonic activity in a cleaning tank will generally benefit from a process of sweeping the frequency of the driving signal at a predetermined rate throughout a predetermined frequency range. With prior generators, however, it was difficult to select or change the range and sweep rate because those parameters were defined by electrical components such as resistors and capacitors that were difficult for a user or operator to access or change.

### SUMMARY OF THE INVENTION

The present invention is an ultrasonic processing apparatus and method having an ultrasonic generator with user-programmable process parameters, including frequency range and sweep rate. Applications for the invention include various ultrasonic processes and apparatus, including cleaning, wire bonding, and plastic welding using ultrasonic transducers.

The ultrasonic generator of the present invention includes a programmable memory device that permits a user or operator to program the frequency range of the driving signal produced and output by the generator, and also to program the rate at which the generator sweeps through the frequency range. The programmed frequency range may be a single or multiple frequency ranges. In addition to programming the frequency range and sweep rate, a user may also program process times and power settings.

In particular, the ultrasonic generator of the present invention includes a user interface adapted for a user to specify parameters that define a frequency range and a sweep rate for the driving signal, a programmable memory coupled to the user interface for storing the frequency range and sweep rate parameters, and an output circuit responsive to the frequency range and sweep rate parameters for generating the driving signal in the frequency range and at the sweep rate specified by the user.

More broadly, the present invention encompasses an ultrasonic system that includes a piezoelectric transducer, an ultrasonic generator coupled to the transducer for supplying a driving signal at a predetermined frequency range and sweep rate, input means for a user to input parameters to specify the predetermined frequency range and sweep rate, and memory means for storing the parameters that specify the predetermined frequency range and sweep rate.

The ultrasonic process of the present invention includes the steps of programming an ultrasonic generator with parameters specifying a frequency range and a sweep rate of a driving signal output by the generator to one or more ultrasonic transducers used in the ultrasonic process, storing the frequency range and sweep rate parameters in a memory or storage device, and generating a driving signal having a frequency within the specified frequency range and varying at the specified sweep rate.

The ultrasonic process of the present invention also includes the steps of providing one or more sandwich style ultrasonic transducers, providing an ultrasonic generator coupled to the one or more transducers and capable of generating a driving signal to power the transducers, inputting parameters that specify two or more frequency ranges and two or more sweep rates, wherein each frequency range specifies a range of frequencies of the driving signal output by the generator and wherein each sweep rate specifies a rate of change of the frequency of the driving signal, storing the frequency ranges and sweep rates in a memory or storage device, selecting one of the stored frequency ranges and one of the stored sweep rates, and controlling the generator to generate the driving signal according to the selected frequency range and selected sweep rate.

The features and advantages described in the specification are not all inclusive, and particularly, many additional features and advantages will be apparent to one of ordinary skill in the art in view of the drawings, specification and claims hereof. Moreover, it should be noted that the language used in the specification has been principally selected for readability and instructional purposes, and may not have been selected to delineate or circumscribe the inventive subject matter, resort to the claims being necessary to determine such inventive subject matter.

### BRIEF DESCRIPTION OF THE DRAWINGS

FIG. 1 is a schematic view of a cleaning tank and attached ultrasonic transducer with a generator that supplies the driving signals to the transducer for creating ultrasonic vibrations in a cleaning fluid in the tank.

FIG. 2 is a graph of the driving signal frequency and time.

### DETAILED DESCRIPTION OF THE PREFERRED EMBODIMENTS

The drawings depict various preferred embodiments of the present invention for purposes of illustration only. One skilled in the art will readily recognize from the following discussion that alternative embodiments of the structures and methods illustrated herein may be employed without departing from the principles of the invention described herein.

The present invention is an ultrasonic processing apparatus and method having an ultrasonic generator with a user-programmable frequency range and a user-programmable sweep rate. The invention allows a user or operator to easily select or change the range or bandwidth of frequencies in which the generator outputs the driving signal that powers the ultrasonic transducer or transducers. The invention also allows the user or operator to easily select or change the sweep rate at which the frequency of the driving signal changes within the selected range or bandwidth. In other words, the sweep rate indicates how quickly the generator “sweeps” the driving signal frequency between the minimum and maximum frequencies that define the selected frequency range or bandwidth. In addition to programming the frequency range and sweep rate, the invention also permits a user to program process times, power settings, and multiple frequency ranges and sweep rates.

The generator of the present invention has a user interface that permits a user to program or otherwise specify the frequency range or bandwidth and the sweep rate for the output driving signal to provide an improved ultrasonic cleaning process. The user inputs one or more frequency ranges and sweep rates, and these parameters are stored in a memory or storage device and used to control the generator output. The generator generates and outputs the driving signal according to the programmed frequency range and sweep rate specified by the user. The frequency range can be specified by the user as minimum and maximum frequencies, or can be specified by a center frequency plus a deviation or bandwidth or sweep width above and below the center frequency. The sweep rate is typically specified by how many times per second the frequency is swept throughout the user-programmed frequency range.

The user interface for controlling the generator is preferably implemented in computer hardware and software. The user inputs the frequency range and sweep rate through a typical computer interface using a keyboard, mouse, and display monitor, or by using an integrated hand-held or portable computing device, which may be hard wired to the generator or connected by a wireless interface. In one implementation, the monitor would display numerous choices for frequency ranges, specified by minimum and maximum frequencies or center frequencies plus plus-or-minus deviations or bandwidth. The display prompts the user to select one or more sets of parameters. The monitor would also display numerous choices for the sweep rate, specified by a frequency such as, for example, 50 Hz, and prompts the user to select one or more sweep rates. In the same way the user may input other parameters for controlling the generator, including power level, process times, and multiple frequency ranges. The parameters input by the user are stored in a memory and/or storage device, such as a disk drive or RAM, and used to control the generator.

For example, in an application involving ultrasonic cleaning, the ultrasonic transducer or transducers may be mounted on the bottom or sides of a tank, or enclosed in an immersible container or mounted on the end or ends of an ultrasonic rod or push-pull transducer and submerged in water or other cleaning fluid in the tank. Preferably, the transducers are sandwich type transducers, having one or more piezoelectric crystals sandwiched between end masses and clamped with a compression screw. Alternatively, the piezoelectric crystals of the transducer may be directly bonded to a quartz or ceramic tank in a cleaning application. The programmable frequency generator of the present invention may be used to drive ultrasonic transducers in applications other than cleaning, such as plastic welding and wire bonding.

The present invention allows a user to program or otherwise select the frequency range and sweep rate output by the generator that drives the transducer or transducers. This capability permits a user to easily experiment with the frequency range and sweep rate so that optimum values for particular applications can be readily found.

The sweeping mechanism of the present invention is incorporated into a programmable ultrasonic generator, which supplies the driving signal that excites the ultrasonic transducer or transducers. The generator includes a user interface including knobs, screws, dials, software, keys or a keyboard, a graphical user interface using a mouse, or other input devices that permit the user to set the frequency range over which the generator operates and also to set the rate at which the generator sweeps through the programmed range. The controls for user programming the frequency range and sweep rate may be analog or digital.

The purpose of this invention is to incorporate a programmable capability in the ultrasonic generator so that the user can use different combinations of bandwidth and sweep rate, as well as other process parameters such as power levels and processing times, and store them in a memory chip or other storage device so that the user can develop different formulations and return to the exact formula from time to time and always get an exact repeatable formulation.

An advantage of the invention is that it allows the user to program the programmable generator and easily try numerous formulations to develop the best formulas. Another advantage is that the memory capabilities may accommodate as many formulas or processes as the user would like to retain in memory. For example, ten programmable memories would provide the user with ten different frequency ranges and sweep rates that can be stored and used.

Another advantage of the invention is that a user need not disclose proprietary formulations or processes and can keep them confidential from other users, other employees, the vendor of the generator, and any other third parties who may be observing the operation of the generator. This enhances the ability to keep formulations secret.

Yet another advantage is that the user can develop and store different formulations for different products that are being processed, each benefiting from a customized program.

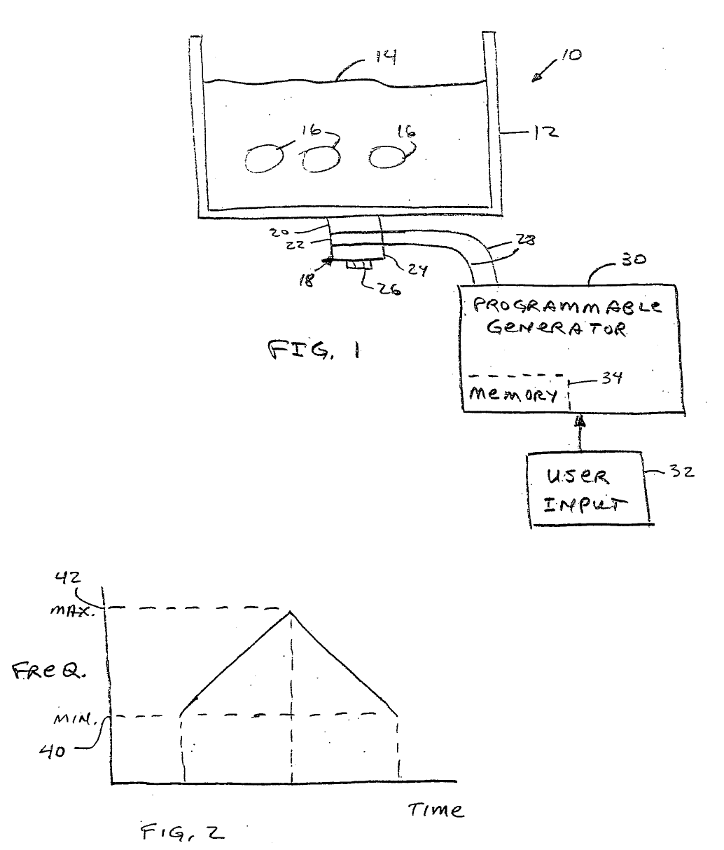

As shown schematically in FIG. 1, a cleaning system 10 utilizing the present invention includes a cleaning tank 12 containing a cleaning liquid or solution 14 and one or more pieces 16 to be cleaned using ultrasonics. Ultrasonic energy is supplied to the cleaning liquid through the tank by one or more ultrasonic transducers 18 affixed to (or immersed in) the tank 12. Typically, a transducer 18 has a sandwich-type construction, with a head mass 20 in contact with the tank, a piezoelectric (PZT) crystal or element 22, a tail mass 24, and a compression fastener or bolt 26. The transducer 18 is driven by a driving signal supplied over electrical wires 28 by a programmable generator 30. The generator 30 is programmed by a user or operator through a user input or interface 32 to set the frequency range or bandwidth and the sweep rate of the driving signal output by the generator, and any other process parameters. The generator includes a memory 34, which is a memory chip, disk drive, or other memory or storage device that stores the frequency ranges, sweep rates, and any other process parameters programmed by the user, and is accessed by the generator circuitry to control the frequencies of the driving signal. The user interface may include a hand-held device for the user to input the process parameters to the programmable generator 30. The user interface 32 may be hard wired to the rest of the programmable generator 30, or may be connected through a wireless interface (not shown). If the user interface 32 is a hand-held wireless device, the memory 34 may reside in the hand-held device.

As shown in FIG. 2, during operation the programmable generator 30 changes the frequencies of the driving signal over time. For example, the driving signal output by the generator may start at a minimum frequency 40 at time T0 and then ramp up linearly to a maximum frequency 42 at time T1 and then ramp back down to the minimum frequency at time T2. The minimum and maximum frequencies are defined by the frequency range or bandwidth programmed by the user and stored in the memory 34 of the generator 30. The rate at which the frequency varies, or the corresponding time period, is determined by the sweep rate programmed by the user and stored in the memory 34 of the generator 30. The generator can be programmed to vary the frequencies of the driving signal according to other programs or functions and need not be limited to linear variations which form a triangular wave or saw tooth pattern shown in FIG. 2. The frequency/time function can be, for example, sinusoidal, exponential, and other functions, as well as linear. The sweep rates need not be the same for sweeping upwards and downwards. The user can also set the number of periods and can establish rest times when the generator shuts off the driving signal, and any other processing variables.

The generator 30 includes the ability to record user-selected frequency ranges and sweep rates, however they are defined by the user, to facilitate experimentation and determination of optimum values for those parameters. The generator 30 and its user input 32 may permit the programming of parameters without displaying them during later operation in order to maintain the confidentiality of the parameters. The programmable generator 30 may output driving signals to several transducers or groups of transducers, by controlling a single or multiple power supplies, each of which outputs a driving signal.

Some ultrasonic transducers may operate within more than one frequency ranges. For example, a wire bonding transducer may have resonant frequencies near 58 KHz and 110 KHz. In such a case, the present invention permits the user to specify frequency ranges and sweep rates at both operational frequencies. For example, the user may set a first center frequency of 57.5 KHz and a first bandwidth of +/−0.5 KHz and a second center frequency of 110.2 KHz and a second bandwidth of +/−1.1 KHz. In this case, the user-programmable parameters would include two or more frequency ranges.

The parameters input by the user may include more than the frequency range and sweep rate. One such parameter is the desired power level of the driving signal. Processing times is another such parameter.

The frequency range may be selected or defined in part by a phase lock loop circuit. An ultrasonic transducer may have a nominal frequency for operating at its lowest or highest impedance, depending on the application. However, individual transducers may vary from the nominal frequency, or may vary with time due to thermal or aging effects. Some generators use a phase lock loop control to determine the operating frequency. The present invention can be implemented in such generators using the phase lock loop circuit to control the center frequency by having the user program the plus and minus deviations or bandwidth relative to that center frequency.

From the above description, it will be apparent that the invention disclosed herein provides a novel and advantageous ultrasonic processing apparatus and method having an ultrasonic generator with a user-programmable frequency range and a user-programmable sweep rate. The foregoing discussion discloses and describes merely exemplary methods and embodiments of the present invention. As will be understood by those familiar with the art, the invention may be embodied in various other forms without departing from the spirit or essential characteristics thereof. Accordingly, the disclosure of the present invention is intended to be illustrative, but not limiting, of the scope of the invention, which is set forth in the following claims.

What is claimed is:

1. An ultrasonic generator operable for generating a driving signal to power one or more ultrasonic transducers, wherein the generator comprises:
a user interface adapted for a user to specify parameters that define a frequency range and a sweep rate for the driving signal;
a programmable memory coupled to the user interface for storing the frequency range and sweep rate parameters; and
an output circuit responsive to the frequency range and sweep rate parameters for generating the driving signal in the frequency range and at the sweep rate specified by the user.

2. An ultrasonic generator as recited in claim 1, wherein the programmable memory further includes a memory that stores multiple sets of frequency range and sweep rate parameters, each defining a frequency range and a sweep rate for the driving signal, and wherein the user interface includes means for selecting a particular frequency range and a particular sweep rate for use by the output circuit.

3. An ultrasonic generator as recited in claim 1, wherein the user interface restricts viewing of the frequency range and sweep rate parameters after they are stored in the programmable memory.

4. An ultrasonic process comprising the steps of:
programming an ultrasonic generator with parameters specifying a frequency range and a sweep rate of a driving signal output by the generator to one or more ultrasonic transducers used in the ultrasonic process;
storing the frequency range and sweep rate parameters in a memory or storage device; and
thereafter, generating a driving signal having a frequency within the specified frequency range and varying at the specified sweep rate.

5. An ultrasonic process as recited in claim 4, further comprising a step of using the ultrasonic process for cleaning.

6. An ultrasonic process as recited in claim 4, further comprising a step of using the ultrasonic process for wire bonding.

7. An ultrasonic process as recited in claim 4, further comprising a step of using the ultrasonic process for plastic welding.

8. An ultrasonic process comprising the steps of:
providing one or more sandwich style ultrasonic transducers;
providing an ultrasonic generator coupled to the one or more transducers and capable of generating a driving signal to power the transducers;
inputting parameters that specify two or more frequency ranges and two or more sweep rates, wherein each frequency range specifies a range of frequencies of the driving signal output by the generator and wherein each sweep rate specifies a rate of change of the frequency of the driving signal;
storing the frequency ranges and sweep rates in a memory or storage device;
selecting one of the stored frequency ranges and one of the stored sweep rates; and
controlling the generator to generate the driving signal according to the selected frequency range and selected sweep rate.

9. An ultrasonic process as recited in claim 8, further comprising the steps of monitoring the results of the ultrasonic process for each selected frequency range and sweep rate, and changing the frequency range and sweep rate to optimize the ultrasonic process.

10. An ultrasonic process as recited in claim 8, wherein the selected frequency range and selected sweep rate are not displayed in order to maintain confidentiality.

11. An ultrasonic system comprising:
a piezoelectric transducer;
an ultrasonic generator coupled to the transducer for supplying a driving signal at a predetermined frequency range and sweep rate;
input means for a user to input parameters to specify the predetermined frequency range and sweep rate; and
memory means for storing the parameters that specify the predetermined frequency range and sweep rate.

12. An ultrasonic system as recited in claim 11, further comprising means for preventing display of the predetermined frequency range and sweep rate to an operator when the generator is supplying the driving signal to the transducer.
